(19) United States
(12) Patent Application Publication
(10) Pub. No.: US 2013/0319317 A1
(43) Pub. Date: Dec. 5, 2013

(54) CRYSTAL PRODUCTION METHOD

(71) Applicant: CHUNG-PEI WANG, Tu-Cheng (TW)

(72) Inventor: CHUNG-PEI WANG, Tu-Cheng (TW)

(73) Assignee: HON HAI PRECISION INDUSTRY CO., LTD., Tu-Cheng (TW)

(21) Appl. No.: 13/600,247

(22) Filed: Aug. 31, 2012

(30) Foreign Application Priority Data
May 30, 2012 (TW) 101119252

(51) Int. Cl. C30B 15/00

(52) U.S. Cl. 117/13

(57) ABSTRACT

A crystal production method includes the following steps. A material is melted in a crucible to form a thin film. A seed crystal is then contacted with the thin film to form a solid-liquid interface, wherein the shape and size of a bottom surface of the seed crystal is the same as the size and shape of the thin film. Finally, the seed crystal is pulled up without rotation, to allow the melted material to solidify at the solid-liquid interface to produce a crystal.

### BACKGROUND

1. Technical Field

The present disclosure relates to a method of producing crystal.

2. Description of Related Art

Man-made crystal, such as sapphire, can be produced by a pulling method (Czochralski method). The method includes the following steps: first, material to be crystallized is melted; secondly, a seed crystal is put into the melted material, and a solid-liquid interface is formed between the seed crystal and the melted material; at last, the seed crystal is pulled up very slowly while being rotated, to form new crystal at the solid-liquid interface. This is a slow procedure, which make the new crystal very expensive.

Therefore, a crystal production method which can overcome the above-mentioned problems is needed.

### BRIEF DESCRIPTION OF THE DRAWINGS

FIGS. 1-3 are schematic views showing a crystal production method according to an exemplary embodiment.

### DETAILED DESCRIPTION

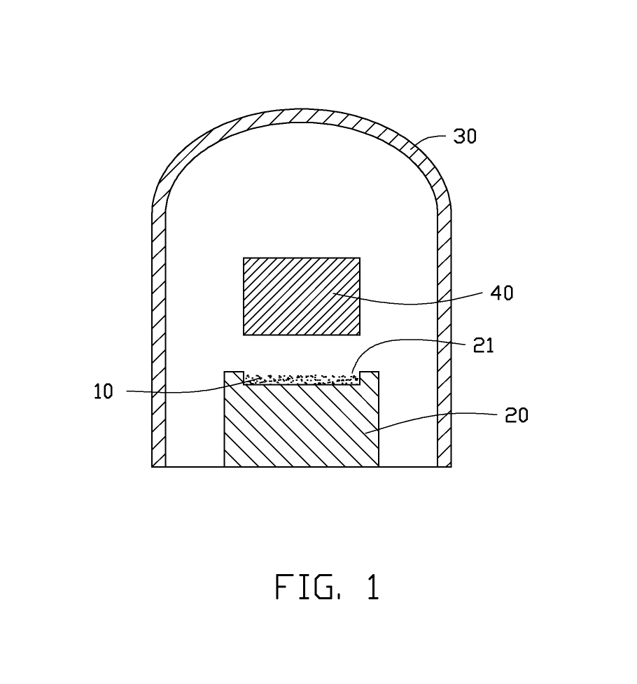

Referring to FIGS. 1 to 3, a crystal production method according to an exemplary embodiment is shown.

FIG. 1 shows material 10 for producing the crystal is put in a crucible 20. The crucible 20 is made of iridium, tungsten, or molybdenum. The crucible 20 defines a groove 21 for receiving the material 10. The crucible 20 is put in a generating furnace 30. The generating furnace 30 is filled with an inert gas, such as nitrogen or argon. The generating furnace 30 further includes a heating device (not shown). As the generating furnace 30 is familiar to a skilled in the art, a detailed description is omitted here.

In this embodiment, the material 10 is Al₂O₃ powder, and the purity of the material 10 is above 99.9%. The material 10 is used for producing a sapphire.

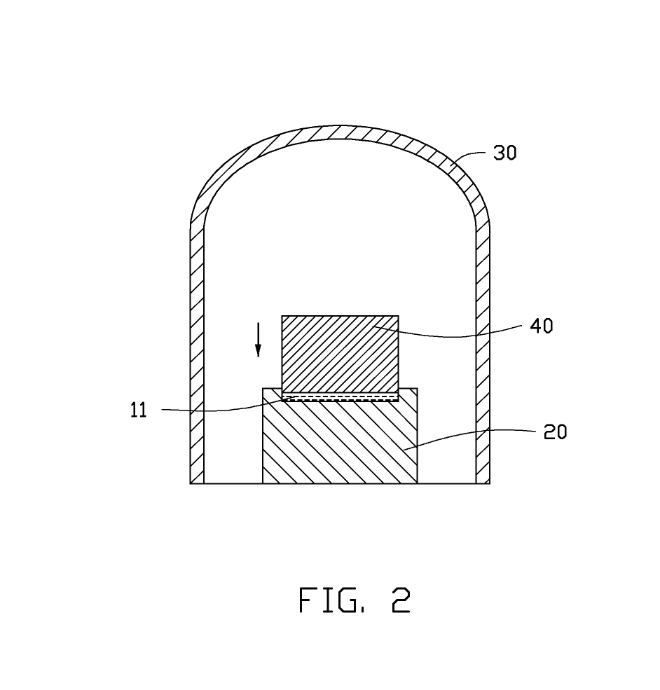

FIG. 2 shows the material 10 is melted to form a thin film 11, and a seed crystal 40 is put into contact with the thin film 11 forming a solid-liquid interface. In this embodiment, the generating furnace 30 heats the crucible 20 to melt the material 10. In this embodiment, the material 10 is heated to about 2050 degrees Celsius. The melted material 10 flows in the groove 21 to form the thin film 11. The seed crystal 40 is a natural sapphire. The shape and size of a bottom surface of the seed crystal 40 is the same as that of the thin film 11.

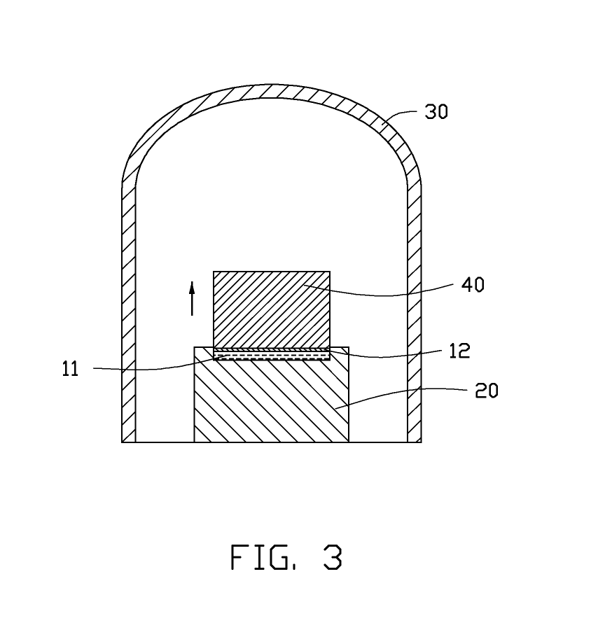

FIG. 3 shows the seed crystal 40 is pulled up slowly and the melted material 10 is solidified at the solid-liquid interface to form a crystal 12. In this embodiment, the pulling speed is about 10 to 25 millimeters per hour. The shape and size of the surface of the crystal 12 perpendicular to the pulling direction is the same as that of the bottom surface of the seed crystal 40, and so the melted material 10 is solidified across the whole surface of the thin film, thus, the seed crystal 40 does not need to be rotated to make the crystal 12 grow along the direction perpendicular to the pulling direction of the seed crystal 40. In this way, the seed crystal 40 can be pulled up more rapidly, and the crystal 12 can be produced more rapidly, which decreases crystal production costs. In this embodiment, the production cost is decreased by about 50%.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A crystal production method, comprising:
putting material to be crystallized in a crucible;
heating to melt the material to form a thin film;
putting a seed crystal into contact with the thin film, to form a solid-liquid interface between a bottom surface of the seed crystal and the thin film, wherein the shape and size of the bottom surface is the same as that of the thin film; and
pulling up the seed crystal without rotation, to make the melted material to solidify at the solid-liquid interface to produce a new crystal.

2. The crystal production method of claim 1, wherein the crucible is put in a generating furnace filled with an inert gas.

3. The crystal production method of claim 2, wherein the new crystal is sapphire.

4. The crystal production method of claim 3, wherein the material is Al₂O₃ powder.

5. The crystal production method of claim 4, wherein in the step of heating to melt the material, the generating furnace heats the material, the material is heated to about 2050 degrees Celsius.
